(19) United States
(12) Patent Application Publication
(10) Pub. No.: US 2011/0205412 A1
(43) Pub. Date: Aug. 25, 2011

(54) SOLID STATE IMAGE SENSOR FOR COLOR IMAGE PICK UP

(75) Inventors: Kenichi MIYAZAKI, Kyoto (JP); Hiroaki SHIRAGA, Kyoto (JP)

(73) Assignee: ROHM CO., LTD.,, Kyoto-fu (JP)

(21) Appl. No.: 13/031,938

(22) Filed: Feb. 22, 2011

(30) Foreign Application Priority Data
Feb. 22, 2010 (JP) P2010-036074

(51) Int. Cl. H04N 5/335

(52) U.S. Cl. 348/294; 348/E05.091

(57) ABSTRACT

A solid state image sensor for color image pick up, including: a circuit section formed on a substrate; a lower electrode layer arranged on the circuit section; a compound semiconductor thin film with a chalcopyrite structure, which is arranged on the lower electrode layer; a transparent electrode layer arranged on the compound semiconductor thin film; and a visible light filter arranged on the transparent electrode layer, wherein the lower electrode layer, the compound semiconductor thin film and the transparent electrode layer are sequentially stacked on the circuit section, and in addition, thin a film thickness of the compound semiconductor thin film below the visible light filter, and absorb only visible light. A solid state image sensor for color image pick up is provided, which does not require an infrared removal filter for luminous efficacy correction, and matches color reproduction characteristics thereof with human luminous efficacy.

### CROSS REFERENCE TO RELATED APPLICATIONS AND INCORPORATION BY REFERENCE

This application is based upon and claims the benefits of priority from prior Japanese Patent Application No. P2010-036074 filed on Feb. 22, 2010, the entire contents of which are incorporated herein by reference.

### TECHNICAL FIELD

The present invention relates to a solid state image sensor for color image pick up, and particularly relates to a solid state image sensor for color image pick up, which does not require an infrared removal filter for luminous efficacy correction, and matches color reproduction characteristics thereof with human luminous efficacy.

### BACKGROUND ART

A thin-film solar cell using, as a light absorption layer, CuInSe₂ (CIS-based thin film) as a semiconductor thin film with a chalcopyrite structure, which is made of Ib-family elements, IIIb-family elements and VIb-family elements, or Cu(In, Ga)Se₂ (CIGS-based thin film) obtained by solid-solving Ga thereinto has advantages in exhibiting high energy conversion efficiency and having a small deterioration of the efficiency owing to light irradiation and the like.

A solid state image sensor, which uses a compound semiconductor thin film with the chalcopyrite structure and has a direct current reduced to a large extent, and a method for manufacturing the same have already been disclosed.

In a single plate-type image sensor that composes the solid state image sensor from only one charge coupled device (CCD) image sensor or a complementary metal oxide semiconductor (CMOS) image sensor, which is usually used as a solid state image element, those different in color for each of pixels are provided as color filters, which perform color separation, on the sensor concerned.

In each of the color filters, spectral transmittance characteristics thereof are designed so as to transmit a target color therethrough. However, these color filters have fixed transmissivity also for a near-infrared wavelength region. Moreover, a photoelectric conversion section of the solid state image element is mainly composed of a semiconductor such as silicon (Si), and accordingly, spectral sensitivity characteristics of the photoelectric conversion section have sensitivity up to such a near-infrared region with a long wavelength. Hence, a signal obtained from the solid state image element provided with the color filters includes a signal component that has reacted to rays of the near-infrared region.

Chromatic vision characteristics as human sensitivity characteristics for colors and relative luminous efficacy characteristics as human sensitivity characteristics for brightness are sensitivity characteristics in which sensitivities range from 380 nm to 780 nm, which is said to be a visible region, and hardly have sensitivities in a wavelength region longer than 700 nm. Accordingly, in order to match color reproduction characteristics of the solid state image element with human luminous efficacy, it is necessary to provide an infrared removal filter for luminous efficacy correction, which does not pass the rays of the near-infrared region to the front of the solid state image element.

### SUMMARY OF THE INVENTION

### Technical Problem

At present, with regard to the CIS-based thin film and the CIGS-based thin film, use thereof as solar cells is a main stream.

The inventors of the present invention are focusing on characteristics of such a compound semiconductor thin film material, which have a high light absorption coefficient, and high sensitivity over a wide wavelength region from the visible light to the near-infrared light, and are examining use of the compound semiconductor thin film material as an image sensor for a security camera (camera that senses the visible light in the daytime, and senses the near-infrared light at night), a personal identification camera (camera for identifying a person by the near-infrared light that is not affected by external light), or an on-board camera (camera mounted on a vehicle in order to assist a visual sense at night, to ensure a remote viewing field, and so on).

It is an object of the present invention to provide a solid state image sensor for color image pick up, which does not require the infrared removal filter for the luminous efficacy correction, and matches color reproduction characteristics thereof with the human luminous efficacy.

### Solution to Problem

In accordance with an aspect of the present invention in order to achieve the foregoing object, a solid state image sensor for color image pick up is provided, which includes: a circuit section formed on a substrate; a lower electrode layer arranged on the circuit section; a compound semiconductor thin film with a chalcopyrite structure, which is arranged on the lower electrode layer; a transparent electrode layer arranged on the compound semiconductor thin film; and a filter arranged on the transparent electrode layer, wherein the lower electrode layer, the compound semiconductor thin film and the transparent electrode layer are sequentially stacked on the circuit section, and in addition, thin a film thickness of the compound semiconductor thin film below the filter, and absorb only visible light.

In accordance with another aspect of the present invention, a solid state image sensor for color image pick up is provided, which includes: a circuit section formed on a substrate; a plurality of word lines WLᵢ (i=1 to m: m is an integer) arranged in a row direction; a plurality of bit lines BLⱼ (j=1 to n: n is an integer) arranged in a column direction; photodiodes including a lower electrode layer, a compound semiconductor thin film with a chalcopyrite structure, which is arranged on the lower electrode layer, and a transparent electrode layer arranged on the compound semiconductor thin film; filters arranged on the transparent electrode layer; and pixels arranged on intersecting portions of the plurality of word lines WLᵢ and the plurality of bit lines BLⱼ, wherein the lower electrode layer, the compound semiconductor thin film and the transparent electrode layer are sequentially stacked on the circuit section, and in addition, thin a film thickness of the compound semiconductor thin film below the filter, and absorb only visible light.

### Advantageous Effects of the Invention

In accordance with the present invention, the solid state image sensor for the color image pick up can be provided, which does not require the infrared removal filter for the luminous efficacy correction, and matches the color reproduction characteristics thereof with the human luminous efficacy.

### BRIEF DESCRIPTION OF DRAWINGS

FIG. 1 is a schematic entire planar pattern configuration view of a solid state image sensor for color image pick up according to a first embodiment of the present invention.

FIG. 2 is a schematic cross-sectional structure view of the solid state image sensor for the color image pick up according to the first embodiment of the present invention.

FIG. 3 is a schematic cross-sectional structure view of a solid state image sensor for color image pick up according to a modification example of the first embodiment of the present invention.

FIG. 4A is an arrangement example of color filters applied to the solid state image sensor for the color image pick up according to the first embodiment of the present invention.

FIG. 4B is another arrangement example of color filters applied to the solid state image sensor for the color image pick up according to the first embodiment of the present invention.

FIG. 5 is transmittance characteristics of the color filters applied to the solid state image sensor for the color image pick up according to the first embodiment of the present invention.

FIG. 6 is wavelength characteristics of quantum efficiencies of compound semiconductor thin films applied to the solid state image sensor for the color image pick up according to the first embodiment of the present invention.

FIG. 7 is light absorption characteristics of the compound semiconductor thin films applied to the solid state image sensor for the color image pick up according to the first embodiment of the present invention.

FIG. 8 is wavelength dependency of the quantum efficiency, which uses a film thickness of the compound semiconductor thin film as a parameter when a Ga content (value of a ratio of Ga to a III family) is equal to 0.4 in the solid state image sensor for the color image pick up according to the first embodiment of the present invention.

FIG. 9 is wavelength dependency of the quantum efficiency, which uses, as a parameter, a Ga content (value of the ratio of Ga to the III family) of the compound semiconductor thin films applied to the solid state image sensor for the color image pick up according to the first embodiment of the present invention.

FIG. 10 is wavelength dependency of the quantum efficiency, which uses, as a parameter, a Cu content (value of a ratio of Cu to the III family) of the compound semiconductor thin film applied to the solid state image sensor for the color image pick up according to the first embodiment of the present invention.

FIG. 11 is a graph showing a relationship between (αhν)² and band gap energy Eg, which uses the Cu content as a parameter in the solid state image sensor for the color image pick up according to the first embodiment of the present invention.

FIG. 12A is a schematic cross-sectional structure view showing a step of a first manufacturing method of the solid state image sensor for the color image pick up according to the first embodiment of the present invention (No. 1).

FIG. 12B is a schematic cross-sectional structure view showing a step of the first manufacturing method of the solid state image sensor for the color image pick up according to the first embodiment of the present invention (No. 2).

FIG. 12C is a schematic cross-sectional structure view showing a step of the first manufacturing method of the solid state image sensor for the color image pick up according to the first embodiment of the present invention (No. 3).

FIG. 13A is a schematic cross-sectional structure view showing a step of the first manufacturing method of the solid state image sensor for the color image pick up according to the first embodiment of the present invention (No. 4).

FIG. 13B is a schematic cross-sectional structure view showing a step of the first manufacturing method of the solid state image sensor for the color image pick up according to the first embodiment of the present invention (No. 5).

FIG. 13C is a schematic cross-sectional structure view showing a step of the first manufacturing method of the solid state image sensor for the color image pick up according to the first embodiment of the present invention (No. 6).

FIG. 14A is a schematic cross-sectional structure view showing a step of the first manufacturing method of the solid state image sensor for the color image pick up according to the first embodiment of the present invention (No. 7).

FIG. 14B is a schematic cross-sectional structure view showing a step of the first manufacturing method of the solid state image sensor for the color image pick up according to the first embodiment of the present invention (No. 8).

FIG. 15A is a schematic cross-sectional structure view showing a step of the first manufacturing method of the solid state image sensor for the color image pick up according to the first embodiment of the present invention (No. 9).

FIG. 15B is a schematic cross-sectional structure view showing a step of the first manufacturing method of the solid state image sensor for the color image pick up according to the first embodiment of the present invention (No. 10).

FIG. 16 is an explanatory view of a forming step of the compound semiconductor thin film in the case where a step difference is not provided in an interlayer insulating film in the first manufacturing method of the solid state image sensor for the color image pick up according to the first embodiment of the present invention.

FIG. 17 is an explanatory view of a forming step of the compound semiconductor thin film in the case where the step difference is provided in the interlayer insulating film in the first manufacturing method of the solid state image sensor for the color image pick up according to the first embodiment of the present invention.

FIG. 18 is a cross-sectional SEM photograph explaining a film thickness suppression effect for the compound semiconductor thin film in the case where the step difference is provided in the interlayer insulating tin film in the first manufacturing method of the solid state image sensor for the color image pick up according to the first embodiment of the present invention.

FIG. 19A is a schematic cross-sectional structure view showing a step of a second manufacturing method of the solid state image sensor for the color image pick up according to the first embodiment of the present invention (No. 1).

FIG. 19B is a schematic cross-sectional structure view showing a step of the second manufacturing method of the solid state image sensor for the color image pick up according to the first embodiment of the present invention (No. 2).

FIG. 20A is a schematic cross-sectional structure view showing a step of the second manufacturing method of the solid state image sensor for the color image pick up according to the first embodiment of the present invention (No. 3).

FIG. 20B is a schematic cross-sectional structure view showing a step of the second manufacturing method of the solid state image sensor for the color image pick up according to the first embodiment of the present invention (No. 4).

FIG. 21A is a schematic cross-sectional structure view showing a step of the second manufacturing method of the solid state image sensor for the color image pick up according to the first embodiment of the present invention (No. 5).

FIG. 21B is a schematic cross-sectional structure view showing a step of the second manufacturing method of the solid state image sensor for the color image pick up according to the first embodiment of the present invention (No. 6).

FIG. 22 is a schematic cross-sectional structure view showing a step of the second manufacturing method of the solid state image sensor for the color image pick up according to the first embodiment of the present invention (No. 7).

FIG. 23 is a schematic cross-sectional structure view showing a step of the second manufacturing method of the solid state image sensor for the color image pick up according to the first embodiment of the present invention (No. 8).

FIG. 24A is a schematic cross-sectional structure view of a photoelectric conversion section in the solid state image sensor for the color image pick up according to the first embodiment of the present invention.

FIG. 25B is a schematic cross-sectional structure view of a compound semiconductor thin film portion in the solid state image sensor for the color image pick up according to the first embodiment of the present invention.

FIG. 25A is a configuration view of a compound semiconductor thin film, which forms a pin junction, in the photoelectric conversion section formed by the manufacturing method of the solid state image sensor for the color image pick up according to the first embodiment of the present invention.

FIG. 25B is an electrical field intensity distribution diagram corresponding to FIG. 25A.

FIG. 26A is a circuit configuration diagram of one pixel in the case of using the Avalanche multiplication in the solid state image sensor for the color image pick up according to the first embodiment of the present invention.

FIG. 26B is a circuit configuration diagram of one pixel in the case of not using the Avalanche multiplication in the solid state image sensor for the color image pick up according to the first embodiment of the present invention.

FIG. 27 is a schematic circuit block configuration diagram of the solid state image sensor for the color image pick up according to the first embodiment of the present invention.

### DESCRIPTION OF EMBODIMENTS

Next, a description is made of embodiments of the present invention with reference to the drawings. In the following description made with reference to the drawings, the same or similar reference numerals are assigned to the same or similar portions. However, it should be noted that the drawings are schematic and are different from the actual ones. Moreover, it is a matter of course that portions different in dimensional relationship and ratio from one another are included also among the drawings.

Moreover, the embodiments shown below illustrate devices and methods for embodying the technical idea of the present invention, and the technical idea of the present invention does not specify arrangement and the like of the respective components to those described below. A variety of alterations can be added to the technical idea of the present invention.

### First Embodiment

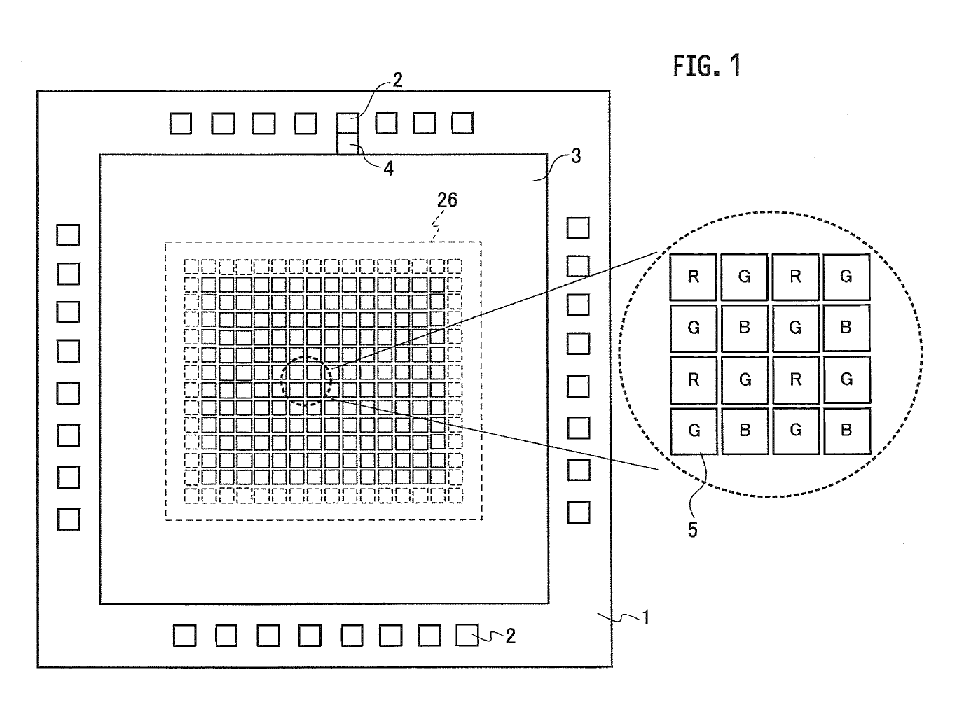

As shown in FIG. 1, a schematic entire planar pattern configuration of a solid state image sensor for color image pick up according to a first embodiment includes: a package substrate 1; a plurality of bonding pads 2 arranged on a peripheral portion on the package substrate 1; and an aluminum electrode layer 3, which is connected to the bonding pad 2 by a bonding pad connecting portion 4, and is connected to a transparent electrode layer 26 arranged on pixels 5 of the solid state image sensor for the color image pick up on a peripheral portion of the solid state image sensor for the color image pick up. Specifically, the aluminum electrode layer 3 coats an end portion region of the transparent electrode layer 26, and the aluminum electrode layer 3 is connected to one bonding pad 2 by the bonding pad connecting portion 4. Moreover, as shown in an inside of an enlarged dotted line circle of FIG. 1, the pixels 5 are arranged in a fine matrix. Moreover, in an example of FIG. 1, in the respective pixels 5, visible light filters for red (R), green (G) and blue (B) are arranged with predetermined regularity on the transparent electrode layer 26. Note that, in the example of FIG. 1, an example of arranging the visible light filters for R, G and B in a Bayer pattern is shown; however, infrared filters may be arranged adjacent to the visible light filters.

### (Solid State Image Sensor for Color Image Pick Up)

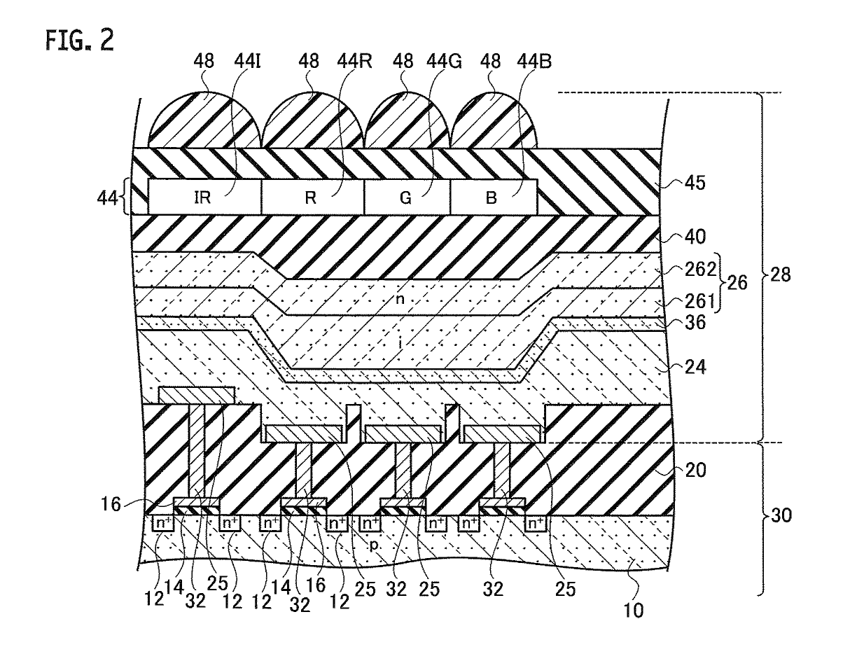

As shown in FIG. 2, a schematic cross-sectional structure of the solid state image sensor for the color image pick up according to the first embodiment includes: a circuit section 30 formed on a semiconductor substrate 10; and a photoelectric conversion section 28 arranged on the circuit section 30.

As shown in FIG. 2, the solid state image sensor for the color image pick up according to the first embodiment includes: the circuit section 30 arranged on the semiconductor substrate 10; a lower electrode layer 25 arranged on the circuit section 30; a compound semiconductor thin film 24 with a chalcopyrite structure, which is arranged on the lower electrode layer 25; a buffer layer 36 arranged on the compound semiconductor thin film 24; a transparent electrode layer 26 arranged on the buffer layer 36; and filters 44 arranged on the transparent electrode layer 26.

Moreover, the lower electrode layer 25, the compound semiconductor thin film 24, the buffer layer 36 and the transparent electrode layer 26 are sequentially stacked on the circuit section 30, and in addition, thin a film thickness of the compound semiconductor thin film 24 below visible light filters 44R, 44G and 44B, and are adapted to absorb only the visible light.

Furthermore, as shown in FIG. 2, infrared filters 44I arranged on the transparent electrode layer 26 may be provided, the film thickness of the compound semiconductor thin film 24 below the visible light filters 44R, 44G and 44B may be thinned more than a film thickness of the compound semiconductor thin film 24 below the infrared filters 44I, and the compound semiconductor thin film 24 below the infrared filters 44I may be adapted to absorb only near-infrared light. Specifically, the solid state image device for the color image pick up according to the first embodiment can also be configured to be given sensitivities for not only the visible light but also for such a near-infrared light region.

Moreover, the buffer layer 36 arranged on the compound semiconductor thin film 24 is integrally formed on the entire surface of a semiconductor substrate. Furthermore, the transparent electrode layer 26 is integrally formed on the entire surface of a semiconductor substrate, and is made electrically common thereto.

An interlayer insulating film 40 is arranged on the transparent electrode layer 26, and the filters 44 are arranged on a planarized surface of the interlayer insulating film 40. Moreover, on the filters 44, a clear filter 45 formed of a passivation film or the like is arranged, and further, on the clear filter 45, micro lenses 48 may be arranged so as to individually correspond to the R, G, B and IR pixels.

In the solid state image sensor for the color image pick up according to the first embodiment, for example, a reverse bias voltage may be applied between the transparent electrode layer 26 and the lower electrode layer 25, and multiplication of electric charges may be caused by photoelectric conversion by means of impact ionization thereof in the compound semiconductor thin film 24 with the chalcopyrite structure.

The circuit section 30 includes transistors in which the lower electrode layer 25 is connected to gates.

In the solid state image sensor for the color image pick up, which is shown in FIG. 2, the compound semiconductor thin film 24 with the chalcopyrite structure is formed of Cu(In_{X}, Ga_{1-X})Se₂ (0≦X≦1).

As the lower electrode layer 25, for example, molybdenum (Mo), niobium (Nb), tantalum (Ta), tungsten (W) and the like can be used.

As a forming material of the buffer layer 36, for example, CdS, ZnS, ZnO, ZnMgO, ZnSe, In₂S₃ and the like can be used.

The transparent electrode layer 26 includes: a semi-insulating layer (iZnO layer) 261 made of a non-doped ZnO film arranged on the compound semiconductor thin film 24; and an upper electrode layer (nZnO layer) 262 made of an n-type ZnO film arranged on the semi-insulating layer 261.

Moreover, the compound semiconductor thin film 24 includes a high-resistance layer (i-type CIGS layer) on a surface thereof.

The circuit section 30 may include, for example, a CMOS field-effect transistor (FET).

In FIG. 2, in the circuit section 30, n-channel MOS transistors which compose apart of the CMOS are shown, and the n-channel MOS transistors include: the semiconductor substrate 10; source/drain diffusion layers 12 formed in the semiconductor substrate 10; gate insulating films 14 arranged on the semiconductor substrate 10 between the source/drain diffusion layers 12; gate electrodes 16 arranged on the gate insulating films 14; and VIA electrodes 32 arranged on the gate electrodes 16.

Both of the gate electrodes 16 and the VIA electrodes 32 are formed in the interlayer insulating film 20.

In the solid state image sensor for the color image pick up, which is shown in FIG. 2, the gate electrodes 16 of the n-channel MOS transistors, which compose a part of the CMOS, and the photoelectric conversion unit 28 are electrically connected to each other by the VIA electrodes 32 arranged on the gate electrodes 16.

Anodes of photodiodes which compose the photoelectric conversion section 28 are connected to the gate electrodes 16 of the n-channel MOS transistors, and accordingly, optical information detected by the photodiodes is amplified by the n-channel MOS transistors concerned.

Note that the circuit section 30 can also be formed, for example, of thin film transistors with a CMOS configuration, which are formed on a thin film formed on a glass substrate.

### Modification Example

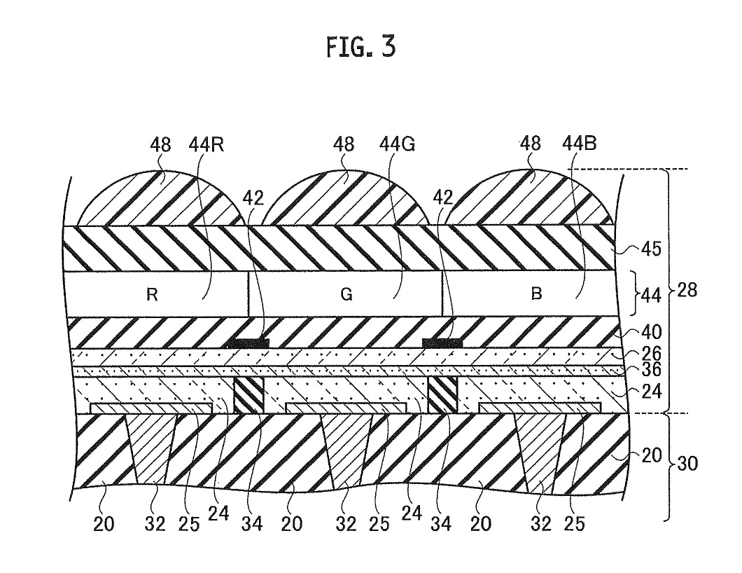

A schematic cross-sectional structure of a solid state image sensor for color image pickup according to a modification example of the first embodiment is illustrated as shown in FIG. 3. FIG. 3 is an enlarged view of pixel region portions for R, G and B, in which the compound semiconductor thin film 24 is thinned, and though not shown, such a pixel for IR, which has the compound semiconductor thin film 24 with a relatively thick film thickness, is arranged adjacent thereto in a similar way to FIG. 2.

As obvious from FIG. 3, among the adjacent pixels, the compound semiconductor thin film 24 arranged on the lower electrode layer 25 is isolated from one another while interposing element isolation regions 34 thereamong. The element isolation regions 34 may also be formed of the interlayer insulating film 20. Moreover, on spots on the transparent electrode layer 26, which correspond to the element isolation regions 34, light shielding layers 42, which have approximately the same width as that of the element isolation regions 34 and are formed, for example, of aluminum (Al) and the like, are arranged.

Note that widths of the compound semiconductor thin film 24 and the lower electrode layer 25 may be equivalent to each other, or in more detail, as shown in FIG. 3, the width of the compound semiconductor thin film 24 may be set so as to become larger than the width of the lower electrode layer 25.

Other configurations are similar to those of the configuration of the solid state image sensor for the color image pick up according to the first embodiment, and accordingly, a duplicate description is omitted.

### (Filters)

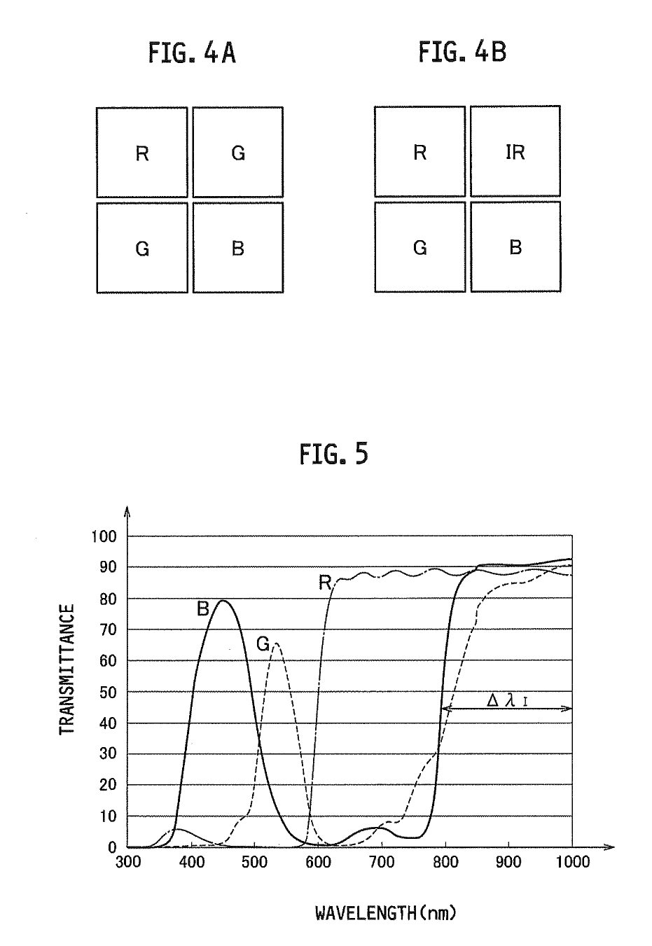

As shown in FIG. 4A, an arrangement example of color filters applied to the solid state image sensor for the color image pick up according to the first embodiment is a Bayer pattern in which the filters for G are arrayed double the filters for R and B. Moreover, as shown in FIG. 4B, the filter for IR may be arranged with respect to the filters for R, G and B. An array method of the filters as described above is not limited to square grid arrays shown in FIG. 4A and FIG. 4B, and for example, a honeycomb array may be adopted. For the color filters, for example, it is possible to apply a color resist using pigment as a base, a transmission resist formed by using a nano-imprinting technology, a gelatin film or the like.

Transmittance characteristics of the color filters applied to the solid state image sensor for the color image pick up according to the first embodiment are represented as shown in FIG. 5. As obvious from FIG. 5, each of the visible light filters for R, G and B has fixed transmissivity also in a near-infrared wavelength range that is other than desired wavelength ranges of R, G and B and is shown by ΔλI. Therefore, as described later, in the solid state image sensor for the color image pick up according to the first embodiment, the thickness and/or band gap energy Eg of the compound semiconductor thin film 24 is controlled, whereby sensitivities for the infrared light and the near-infrared light are shut off.

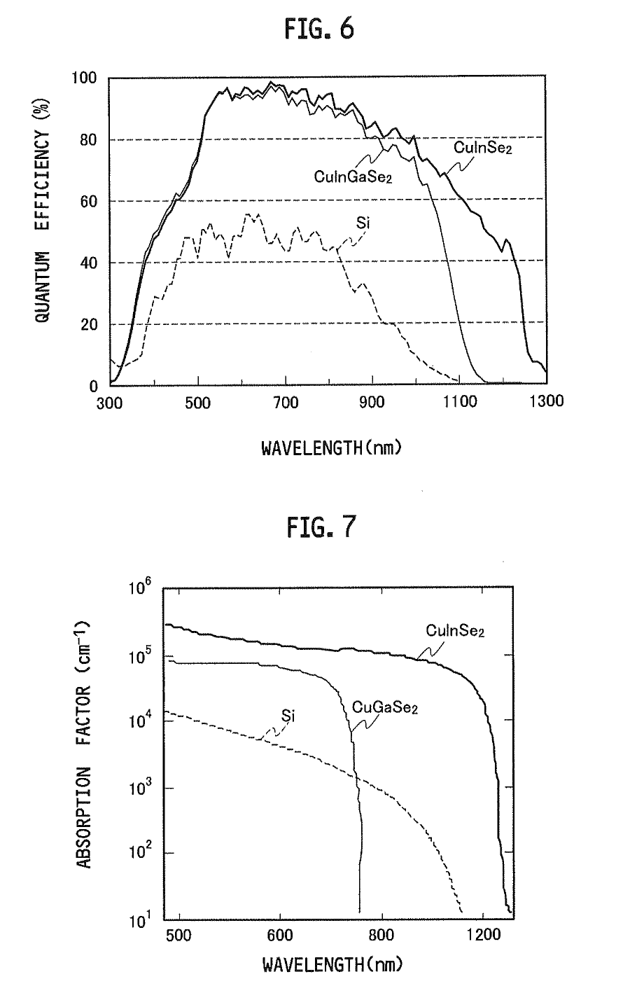

Wavelength characteristics of quantum efficiency of the CIGS film applied to the solid state image sensor for the color image pick up according to the first embodiment are represented as shown in FIG. 6. Specifically, the compound semiconductor thin film (Cu(In_{X}, Ga_{1-X})Se₂ (0≦x≦1)) 24 with the chalcopyrite structure, which functions as the light absorption layer, exhibits photoelectric conversion characteristics with high quantum efficiency in a wide wavelength region from the visible light to the near-infrared light. The quantum efficiency is double or more that of photoelectric conversion characteristics in the case of silicon (Si). In particular, in mixed crystal of CuInSe₂ and CuGaSe₂, the highest value of the quantum efficiency is obtained in the visible light region.

Light absorption characteristics of the CIGS film applied to the solid state image device for the color image pick up according to the first embodiment are represented as shown in FIG. 7. Specifically, the compound semiconductor thin film (Cu(In_{X}, Ga_{1-X})Se₂ (0≦X≦1)) 24 with the chalcopyrite structure, which functions as the light absorption layer, has a strong absorption capability in the wide wavelength region from the visible light to the near-infrared light.

For example, the light absorption characteristics are approximately hundred times an absorption factor of silicon (Si) even in the visible light region.

### (Film Thickness Dependency of CIGS Film)

In the solid state image sensor for the color image pick up according to the first embodiment, the film thickness of the compound semiconductor thin film (Cu(In_{X}, Ga_{1-X})Se₂ (0≦X≦1)) 24 with the chalcopyrite structure, which functions as the light absorption layer, is controlled, whereby the quantum efficiency can be controlled.

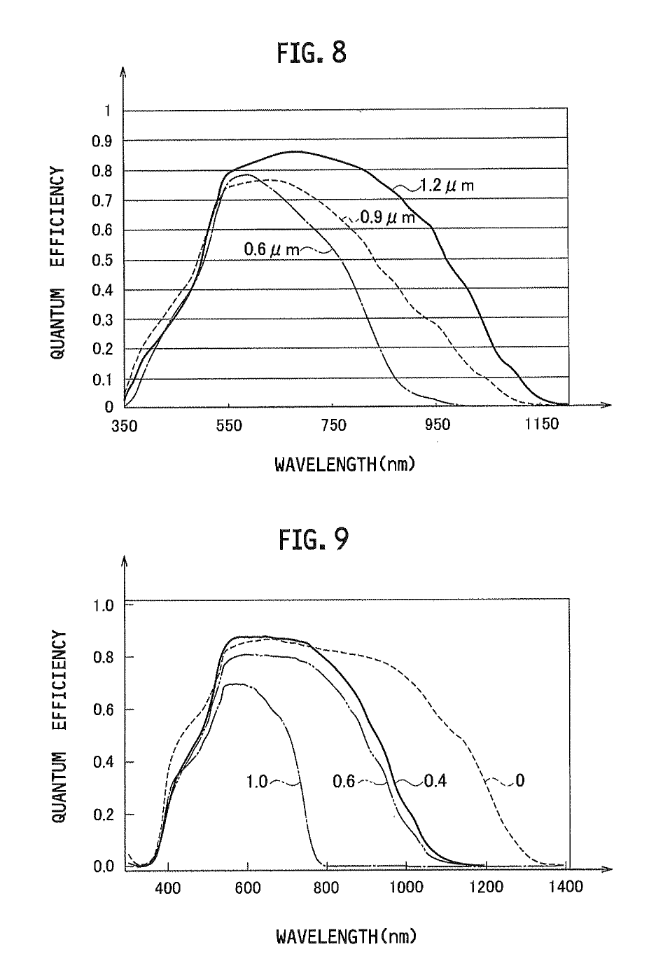

In the solid state image sensor for the color image pick up according to the first embodiment, wavelength dependency of the quantum efficiency, which uses the film thickness of the compound semiconductor thin film 24 as a parameter when a Ga content (value of a ratio of Ga to a III family) is equal to 0.4 is represented as shown in FIG. 8. For example, in the case where the film thickness of the compound semiconductor thin film 24 is 1.2 μm, a wavelength range where the value of the quantum efficiency becomes 0.3 or more is from approximately 400 nm to approximately 1050 nm, in the case where the film thickness is 0.9 μm, the wavelength range where the value of the quantum efficiency becomes 0.3 or more is from approximately 400 nm to approximately 950 nm, and in the case where the film thickness is 0.6 μm, the wavelength range where the value of the quantum efficiency becomes 0.3 or more is from approximately 400 nm to approximately 850 nm. It is understood that, as the film thickness of the compound semiconductor thin film 24 is being thinned from 1.2 μm through 0.9 μm to 0.6 μm, the wavelength range where a predetermined value of the quantum efficiency is obtained is narrowed.

In the solid state image sensor for the color image pick up according to the first embodiment, the film thickness of the compound semiconductor thin film 24 with the chalcopyrite structure, which functions as the light absorption layer, is controlled, whereby the quantum efficiency can be given particularly in the visible light region. Therefore, in the solid state image sensor for the color image pick up according to the first embodiment, as shown in FIG. 2, the compound semiconductor thin film 24 is thinned, and the visible light filters 44R, 44G and 44B are arranged on the transparent electrode layer 26 while interposing the interlayer insulating film 40 therebetween, whereby it becomes possible to absorb only incident light in wavelength ranges corresponding to R, G and B.

Meanwhile, in the solid state image sensor for the color image pick up according to the first embodiment, the film thickness of the compound semiconductor thin film 24 with the chalcopyrite structure, which functions as the light absorption layer, is set at a predetermined thickness, whereby the quantum efficiency can be particularly given to the wavelength ranges of the infrared light and the near-infrared light. Therefore, as shown in FIG. 2, the compound semiconductor thin film 24 is set at a predetermined thickness, and the infrared filters 44I are arranged on the transparent electrode layer 26 while interposing the interlayer insulating film 40 therebetween, whereby it also becomes possible to absorb only incident light in the wavelength ranges corresponding to the infrared light and the near-infrared light.

Given the above, in the solid state image sensor for the color image pick up according to the first embodiment, the quantum efficiency can be given not only to the visible light but also to the wavelength ranges of the infrared light and the near-infrared light, and accordingly, the solid state image sensor for the color image pick up according to the first embodiment is also applicable to a solid state image sensor that combines both of the visible light and the infrared and near-infrared light with each other. For example, the solid state image sensor for the color image pick up according to the first embodiment is suitable as a solid state image sensor for a security camera, which senses the visible light in the day time and senses the near-infrared light at night.

### (Band Gap Energy Control for CIGS Film)

In the solid state image sensor for the color image pick up according to the first embodiment, the quantum efficiency can be controlled also in such a manner that a value of the band gap energy of the compound semiconductor thin film (Cu(In_{X}, Ga_{1-X})Se₂ (0≦X≦1)) 24 with the chalcopyrite structure, which functions as the light absorption layer, is also controlled. Specifically, the wavelength range where the predetermined quantum efficiency is obtained can be controlled by controlling the band gap energy Eg of the compound semiconductor thin film 24. Accordingly, for example, a configuration can also be adopted, in which the wavelength range is set at the visible light, and the near-infrared light is not absorbed.

Here, when h is a Planck's constant, c is a speed of light, and λ is a wavelength of light to be absorbed, the band gap energy Eg is represented by hc/λ (Eg=hc/λ), and accordingly, the wavelength range can be narrowed, for example, by increasing a value of the band gap energy Eg.

### —Ga Content Dependency—

In the solid state image sensor for the color image pick up according to the first embodiment, wavelength dependency of the quantum efficiency, which uses, as a parameter, the Ga content (value of a ratio of Ga to the III family) of the compound semiconductor thin film (Cu(In_{X}, Ga_{1-X})Se₂ (0≦x≦1)) 24, is represented as shown in FIG. 9. The Ga content is represented by Ga/(Ga+In). A value of the Ga content is increased from 0 through 0.4 and 0.6 to 1.0, whereby the value of the band gap energy Eg of the compound semiconductor thin film (Cu(In_{X}, Ga_{1-X})Se₂ (0≦X≦1)) 24 can be increased. Accordingly, as a result, as shown in FIG. 9, the wavelength range where the predetermined quantum efficiency is obtained can be narrowed.

In the solid state image sensor for the color image pick up according to the first embodiment, the Ga content of the compound semiconductor thin film 24 is set, for example, at 0.4 to 1.0, whereby it is possible to shut off the infrared light and the near-infrared light, and to set the predetermined value of the quantum efficiency in the wavelength range of the visible light.

Note that, in the solid state image sensor for the color image pick up according to the first embodiment, similar effects can also be obtained by reducing an In content (value of a ratio of In to the III family) of the compound semiconductor thin film (Cu(In_{X}, Ga_{1-X})Se₂ (0≦X≦1)) 24. Reasons for this are as follows. Specifically, the In content is represented by In/(Ga+in), and accordingly, the value of the band gap energy Eg of the compound semiconductor thin film 24 can be increased by reducing the value of the In content. Accordingly, as a result, the wavelength range where the predetermined quantum efficiency is obtained can be narrowed.

### —Cu Content Dependency—

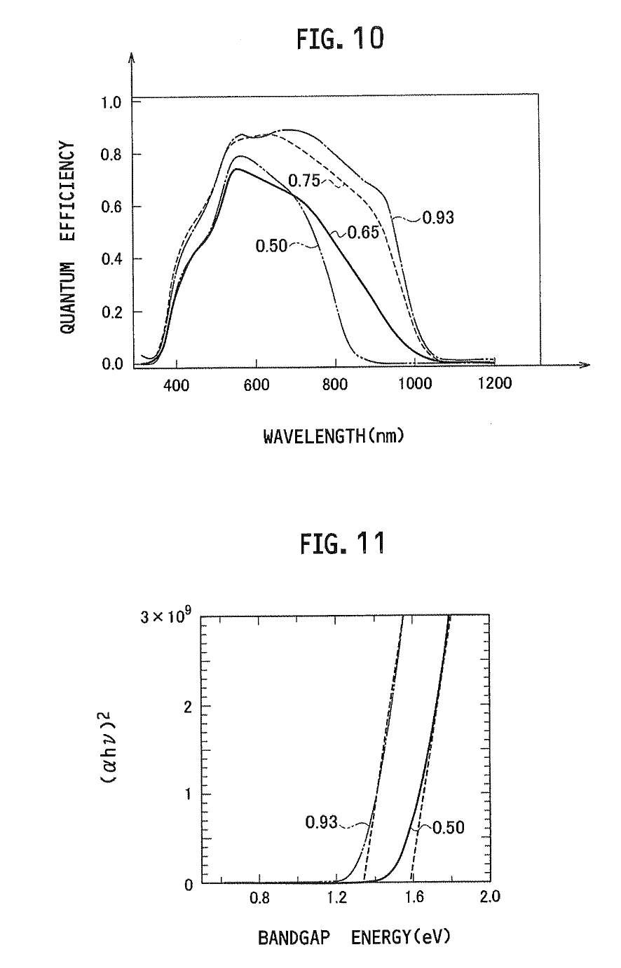

In the solid state image sensor for the color image pick up according to the first embodiment, wavelength dependency of the quantum efficiency, which uses, as a parameter, a Cu content (value of a ratio of Cu to the III family) of the compound semiconductor thin film (Cu(In_{X}, Ga_{1-X})Se₂ (0≦X≦1)) 24, is represented as shown in FIG. 10. The Cu content is represented by Cu/(Cu+In). A value of the Cu content is reduced from 0.93 through 0.75 and 0.63 to 0.50, whereby the value of the band gap energy Eg of the compound semiconductor thin film (Cu(In_{X}, Ga_{1-X})Se₂ (0≦X≦1)) 24 can be increased. Accordingly, as a result, as shown in FIG. 10, the wavelength range where the predetermined quantum efficiency is obtained can be narrowed.

In the solid state image sensor for the color image pick up according to the first embodiment, the Cu content of the compound semiconductor thin film 24 is set, for example, at 0.5 to 1.0, whereby it is possible to shut off the infrared light and the near-infrared light, and to set the predetermined value of the quantum efficiency in the wavelength range of the visible light.

In the solid state image sensor for the color image pick up according to the first embodiment, a relationship between (αhν)² and the band gap energy Eg, which uses the Cu content as a parameter, is represented as shown in FIG. 11. Here, α indicates an absorption coefficient (cm⁻¹), and ν indicates a frequency.

When A is a proportionality constant, the absorption coefficient α is represented by A(hν−Eg)^{1/2}/(hν) (α=A(hν−Eg)^{1/2}/(hν)). Accordingly, the following relationship is established: (αhν)²=A²(hν−Eg). Specifically, as shown in FIG. 11, when the Cu content is reduced from 0.93 to 0.50, the value of the band gap energy Eg can be shifted, for example, from approximately 1.35 eV to approximately 1.6 eV. This is because the value of the band gap energy Eg of the compound semiconductor thin film 24 can be increased when the Cu content is reduced.

In the solid state image sensor for the color image pick up according to the first embodiment, the band gap energy Eg is controlled simultaneously with the film thickness of the compound semiconductor thin film 24, whereby a configuration can be realized, in which pixel portions having the visible light filters arranged therein absorb only the visible light, and pixel portions having the near-infrared filters arranged therein absorb only the near-infrared light.

### (First Manufacturing Method)

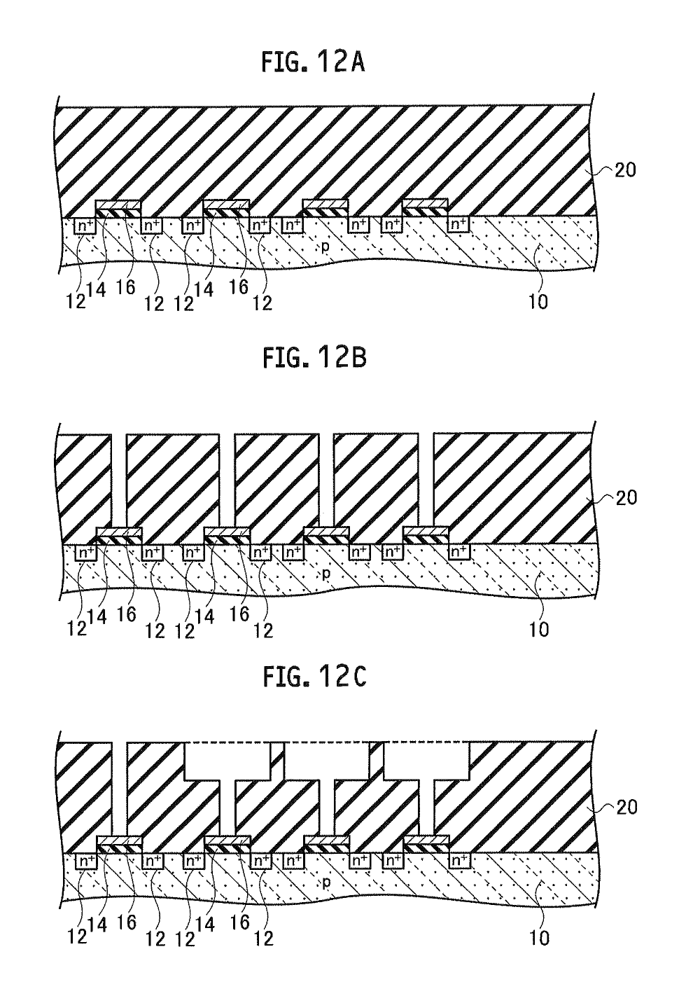

A first manufacturing method of the solid state image sensor for the color image pick up according to the first embodiment is illustrated as shown in FIG. 12 to FIG. 18. In the first manufacturing method, a step difference structure is formed in the interlayer insulating film 20 in advance in order to form a step difference structure in the compound semiconductor thin film 24.

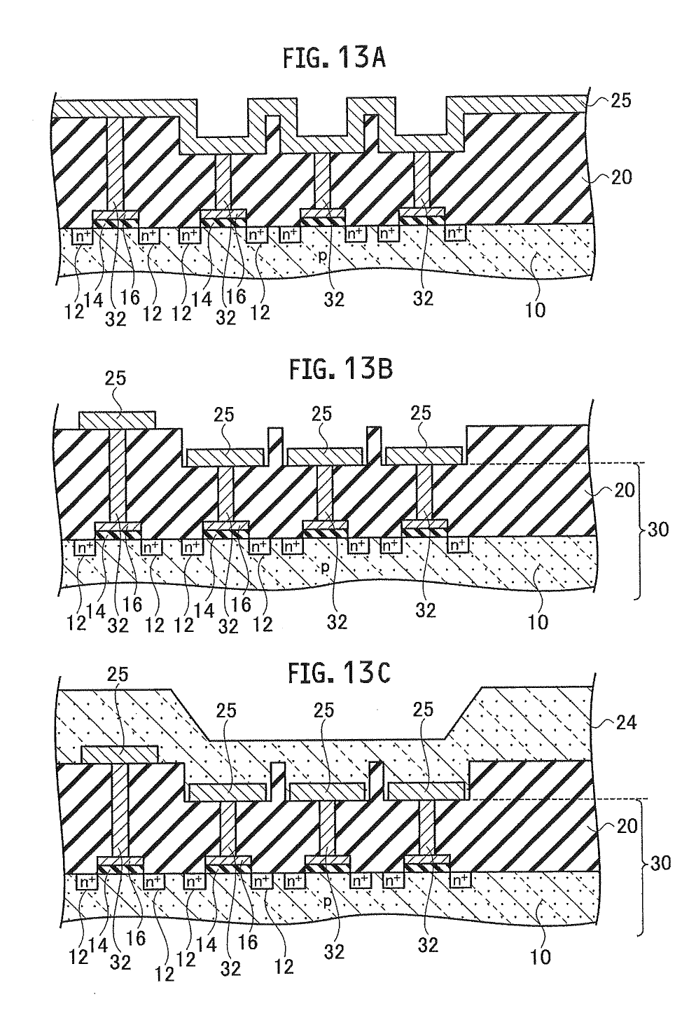

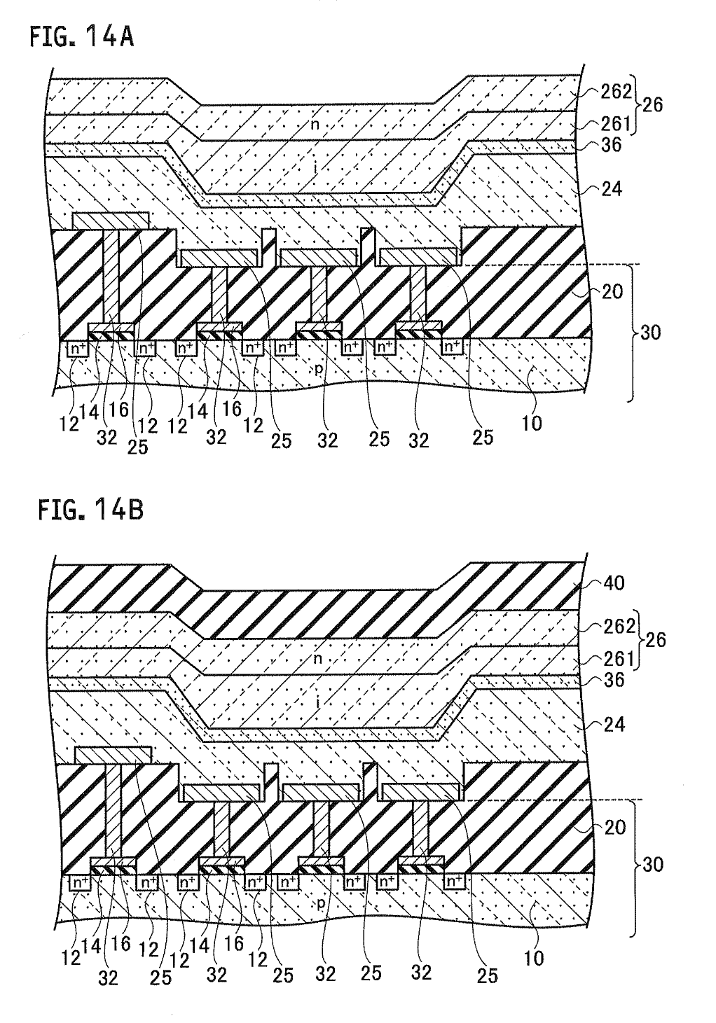

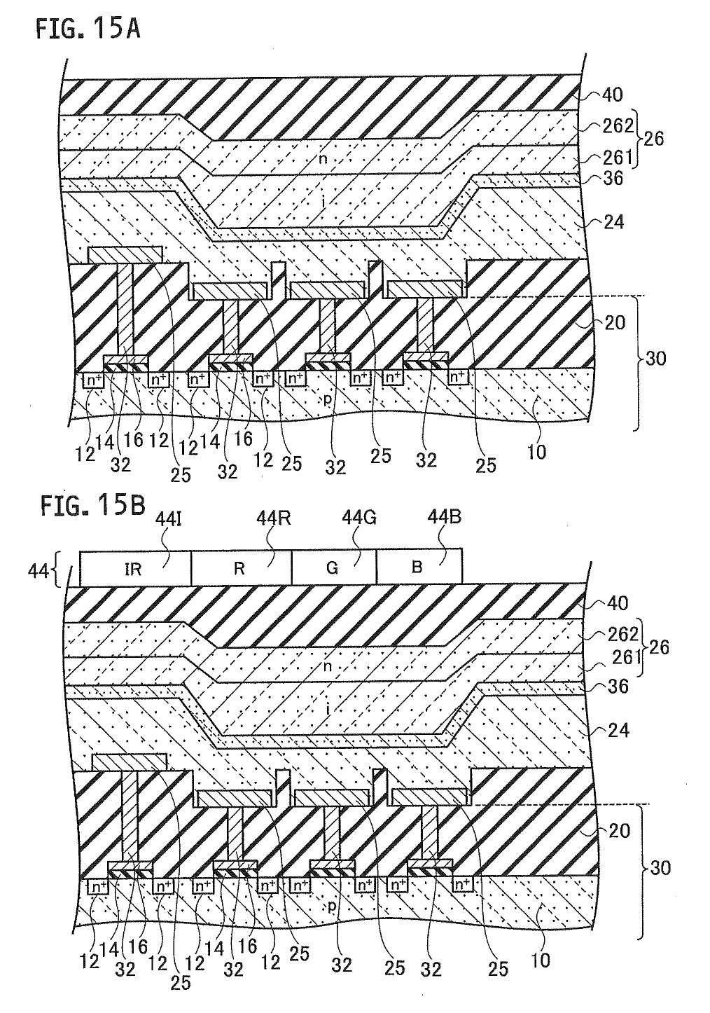

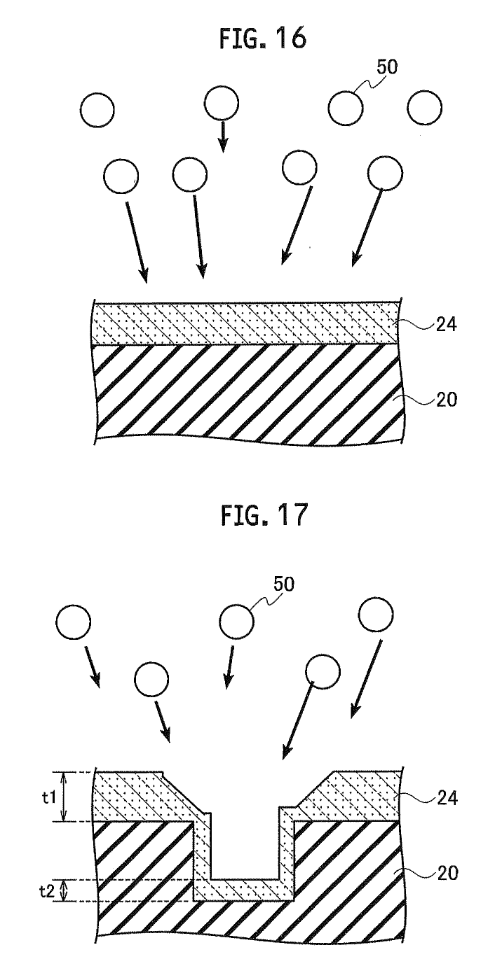

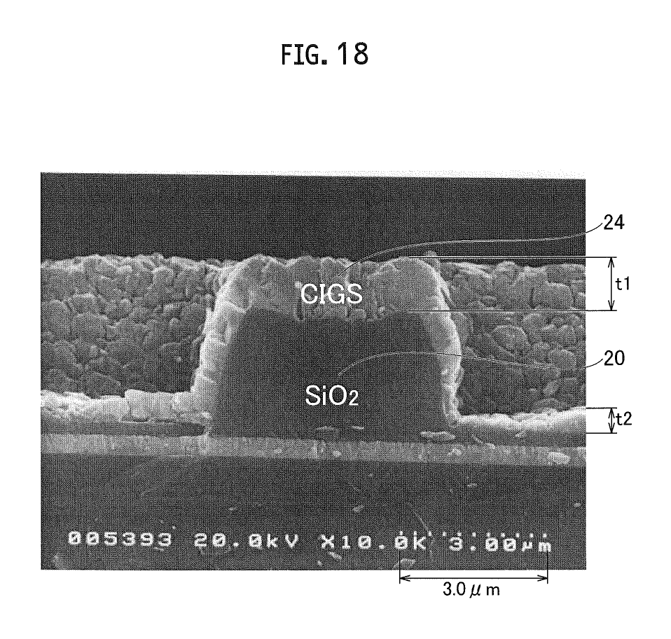

(a) First, as shown in FIG. 12A, the source/drain diffusion layers 12, the gate insulating films 14 and the gate electrodes 16 are formed on the semiconductor substrate 10, and thereafter, the interlayer insulating film 20 is deposited thereon. The interlayer insulating film 20 can be formed, for example, of a silicon oxide film, a silicon nitride film or a composite film of theses. Moreover, the interlayer insulating film 20 can be formed by a chemical vapor deposition (CVD) method, a sputtering method, a vacuum evaporation method and the like.
(b) Next, as shown in FIG. 12B, VIA holes are formed for the interlayer insulating film 20 by using a reactive ion etching (RIE) technology. The gate electrodes 16 are exposed to bottom portions of the VIA holes.
(c) Next, as shown in FIG. 12C, in the pixel regions for detecting the visible light of R, G and B, the interlayer insulating film 20 is partially removed by etching by further using the RIE technology, whereby the interlayer insulating film 20 is thinned, and the step difference structure is formed in the interlayer insulating film 20. In the pixel regions for detecting the infrared and near-infrared light, the interlayer insulating film 20 is not thinned. Note that, as shown in FIG. 12C, walls made of the interlayer insulating film 20 are formed among the adjacent pixels, whereby the element isolation regions made of the interlayer insulating film 20 are formed. A pattern pitch among the adjacent pixels is, for example, approximately 6 to 8 μm, and a height of the walls which are made of the interlayer insulating film 20 and are formed among the adjacent pixels is, for example, approximately 300 nm to 500 nm.
(d) Next, as shown in FIG. 13A, the metal layers (25, 32) made of molybdenum (Mo), niobium (Nb), tantalum (Ta), tungsten (W) or the like are formed on a surface of the interlayer insulating film 20.
(e) Next, as shown in FIG. 13B, the metal layers (25, 32) are patterned, whereby the VIA electrodes 32 and the lower electrode layer 25 are formed.
(f) Next, as shown in FIG. 13C, the compound semiconductor thin film (Cu(In_{X}, Ga_{1-X})Se₂ (0≦X≦1)) 24 is formed on the interlayer insulating film 20 having the step difference structure and on the lower electrode layer 25.
(f-1) In a manufacturing method of the solid state image sensor for the color image pick up according to the first embodiment, in a forming step of the compound semiconductor thin film 24 in the case where the step differences are not provided in the interlayer insulating film 20, as shown in FIG. 16, airborne elements 50 of the forming elements of the CIGS are uniformly deposited on the interlayer insulating film 20.
(f-2) Meanwhile, in the case where the step difference structure is provided on the interlayer insulating film 20, as shown in FIG. 17, the airborne elements 50 of the forming elements of the CIGS are controlled by step difference portions. Therefore, a thickness t2 of the compound semiconductor thin film 24 deposited on the interlayer insulating film 20 of such a step difference portion becomes thinner in comparison with a thickness t1 of the compound semiconductor thin film 24 deposited on the interlayer insulating film 20 of a flat portion. For example, while a value of t1 is approximately 1.2 μm for example, a value of t2 is approximately 0.9 pin for example. FIG. 18 shows a cross-sectional SEM photograph of the compound semiconductor thin film 24 in the case where the step difference is provided on the interlayer insulating film 20. As obvious from FIG. 18, t1 is obviously larger than t2. Accordingly, it is understood that the film thickness of the compound semiconductor thin film 24 on which the step difference portion is formed is suppressed by providing the step difference structure on the interlayer insulating film 20.
(g) Next, as shown in FIG. 14A, the buffer layer 36, the semi-insulating layer (iZnO layer) 261 and the upper electrode layer (nZnO layer) 262 are sequentially formed on the compound semiconductor thin film 24.
(h) Next, as shown in FIG. 14B, the interlayer insulating film 40 is formed on the upper electrode layer (nZnO layer) 262 by similar material and forming method to those of the interlayer insulating film 20.
(i) Next, as shown in FIG. 15A, the interlayer insulating film 40 is planarized. To a step of this planarization, for example, a chemical mechanical polishing (CMP) technology can be applied.
(j) Next, as shown in FIG. 15B, the filters 44 are formed on the planarized interlayer insulating film 40. On the spots of the interlayer insulating film 40, which correspond to the pixel regions for detecting the visible light of R, G and B, the visible light filters 44R, 44G and 44B are arranged, and on the spots of the interlayer insulating film 40, which correspond to the pixel regions for detecting the infrared light, the infrared filters 44I are arranged.
(k) Next, as shown in FIG. 2, the clear filter 45 made, for example, of the passivation film is formed on the filters 44 and the interlayer insulating film 40, and thereafter, on the clear filter 45 on the visible light filters 44R, 44G and 44B and the infrared filters 44I, the micro lenses 48 for collecting the optical information are individually arranged, whereby the solid state image sensor for the color image pick up according to the first embodiment is completed.

### (Second Manufacturing Method)

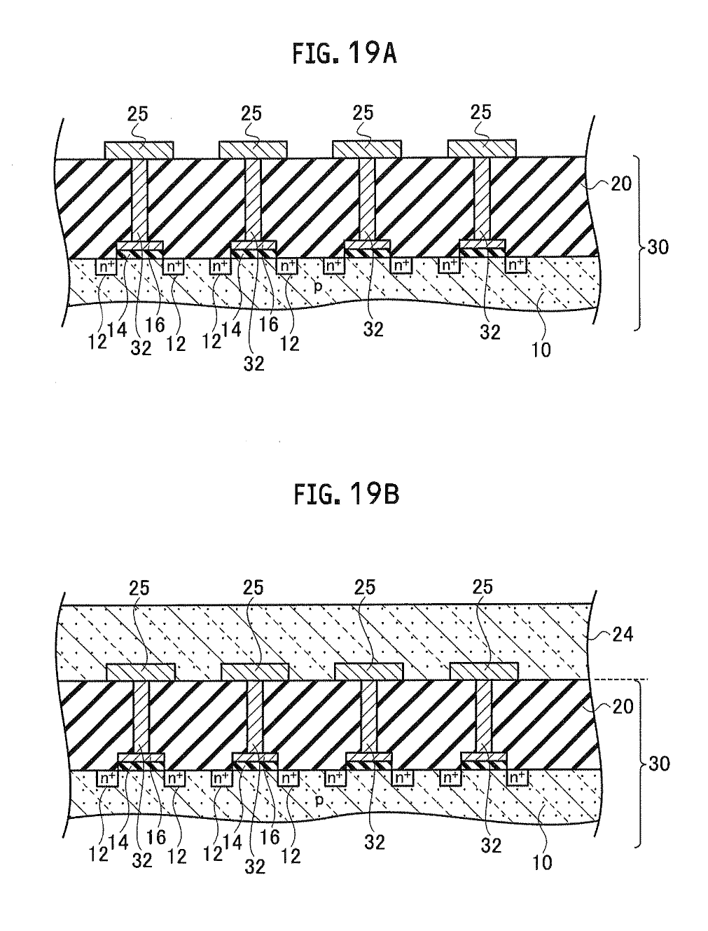

A second manufacturing method of the solid state image sensor for the color image pick up according to the first embodiment is illustrated as shown in FIG. 19 to FIG. 23. In the second manufacturing method, the step difference structure is directly formed in the compound semiconductor thin film 24.

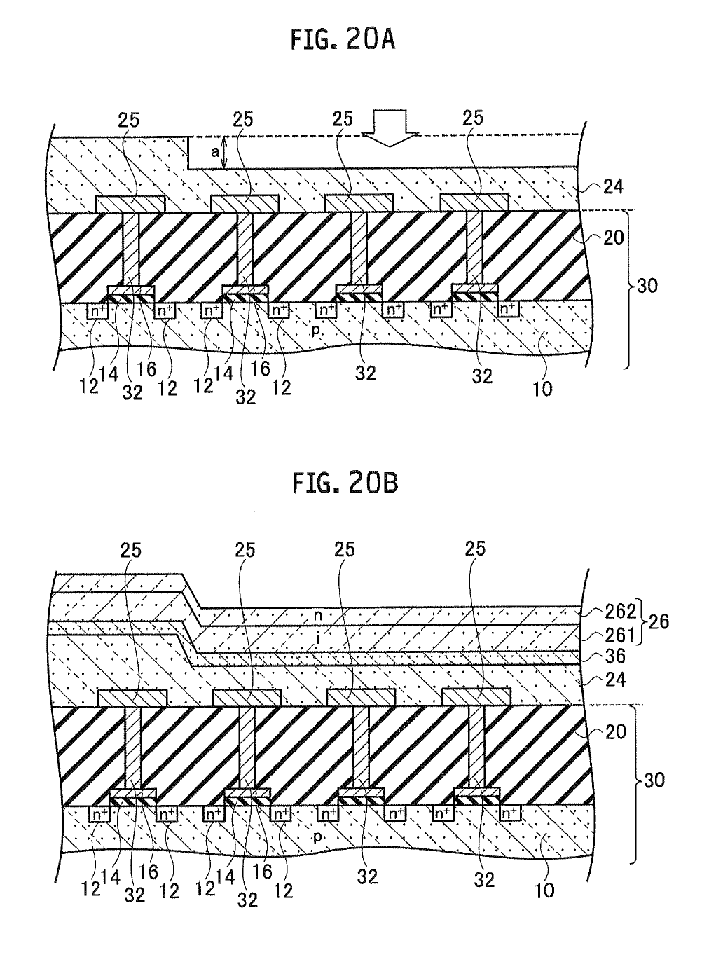

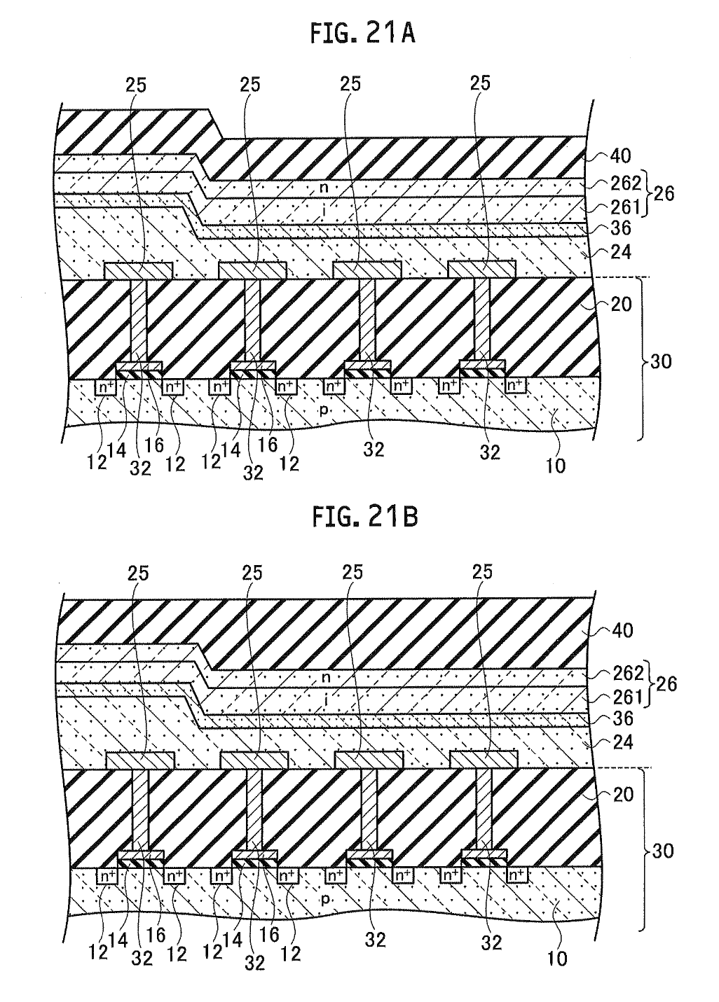

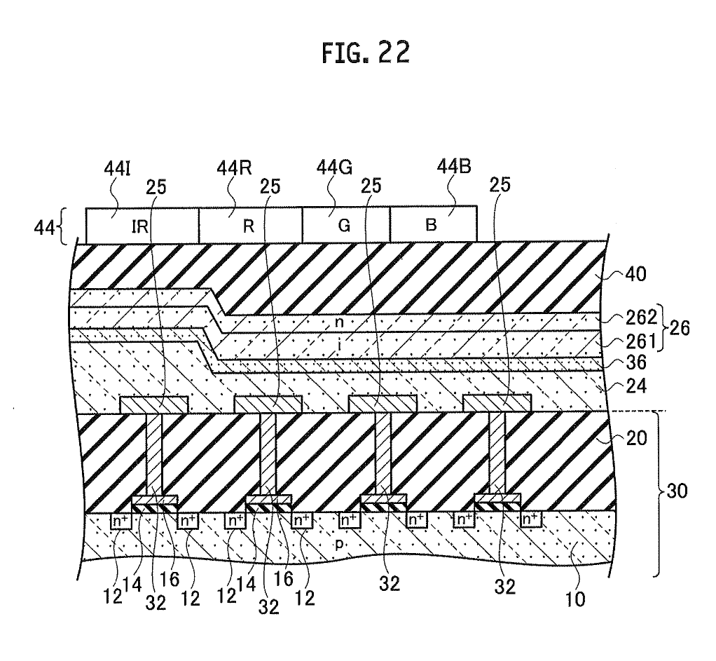

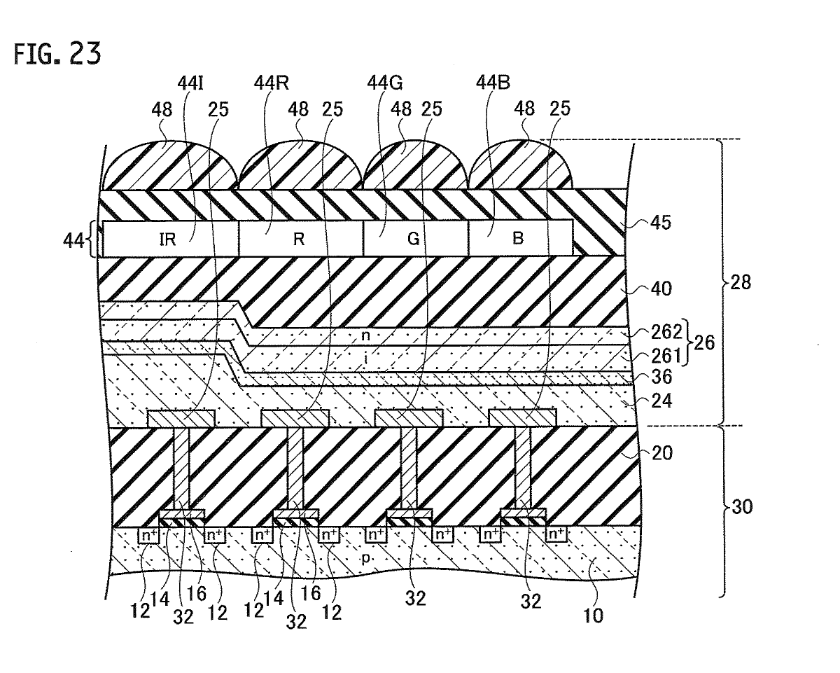

(a) First, as shown in FIG. 19A, the source/drain diffusion layers 12, the gate insulating films 14 and the gate electrodes 16 are formed on the semiconductor substrate 10, and thereafter, the interlayer insulating film 20 is deposited thereon. The interlayer insulating film 20 can be formed, for example, of the silicon oxide film, the silicon nitride film or the composite film of theses. Moreover, the interlayer insulating film 20 can be formed by the CVD method, the sputtering method, the vacuum evaporation method and the like. Next, the VIA holes are formed for the interlayer insulating film 20 by using the RIE technology, and thereafter, the metal layers (25, 32) made of molybdenum (Mo), niobium (Nb), tantalum (Ta), tungsten (W) or the like are formed on the surface of the interlayer insulating film 20, and the metal layers (25, 32) are patterned, whereby the VIA electrodes 32 and the lower electrode layer 25 are formed.
(b) Next, as shown in FIG. 19B, the compound semiconductor thin film (Cu(In_{X}, Ga_{1-X})Se₂ (0≦X≦1)) 24 is formed on the interlayer insulating film 20 and the lower electrode layer 25.
(c) Next, as shown in FIG. 20A, in the pixel regions for detecting the visible light of R, G and B, the compound semiconductor thin film 24 is removed by a thickness a by etching by using the RIE technology, whereby the compound semiconductor thin film 24 is thinned, and the step difference structure is formed in the compound semiconductor thin film 24. In the pixel regions for detecting the infrared and near-infrared light, the compound semiconductor thin film 24 is not thinned.
(d) Next, as shown in FIG. 20B, the buffer layer 36, the semi-insulating layer (iZnO layer) 261 and the upper electrode layer (nZnO layer) 262 are sequentially formed on the compound semiconductor thin film 24.
(e) Next, as shown in FIG. 21A, the interlayer insulating film 40 is formed on the upper electrode layer (nZnO layer) 262 by similar material and forming method to those of the interlayer insulating film 20.
(f) Next, as shown in FIG. 21B, the interlayer insulating film 40 is planarized. To a step of this planarization, for example, the CMP technology can be applied.
(g) Next, as shown in FIG. 22, the filters 44 are formed on the planarized interlayer insulating film 40. On the spots of the interlayer insulating film 40, which correspond to the pixel regions for detecting the visible light of R, G and B, the visible light filters 44R, 44G and 44B are arranged, and on the spots of the interlayer insulating film 40, which correspond to the pixel regions for detecting the infrared light, the infrared filters 44I are arranged.
(h) Next, as shown in FIG. 23, the clear filter 45 made, for example, of the passivation film is formed on the filters 44 and the interlayer insulating film 40, and thereafter, on the clear filter 45 on the visible light filters 44R, 44G and 44B and the infrared filters 44I, the micro lenses 48 for collecting the optical information are individually arranged, whereby the solid state image sensor for the color image pick up according to the first embodiment is completed.

### (Forming Step of Compound Semiconductor Thin Film)

It is possible to form the compound semiconductor thin film, which functions as the light absorption layer, above the semiconductor substrate 10 on which the circuit section 30 is formed or above the glass substrate by the vacuum evaporation method or the sputtering method, which is called a physical vapor deposition (PVD) method, or by a molecular beam epitaxy (MBE) method. Here, the PVD method refers to a method of depositing raw materials evaporated in vacuum, and then forming the deposited raw materials into a film.

In the case of using the vacuum evaporation method, the respective components (Cu, In, Ga, Se, S) of the compound are used as separate evaporation sources, and are evaporated on the substrate on which the circuit section 30 is formed.

In the sputtering method, a chalcopyrite compound is used as a target, or respective components thereof are separately used as targets.

Note that, in the case of forming the compound semiconductor thin film on the glass substrate on which the circuit section 30 is formed, the substrate is heated to a high temperature, and accordingly, a composition shift owing to separation of chalcogenide elements sometimes occurs therein. In this case, after the deposition, the compound semiconductor thin film is subjected to heat treatment for approximately 1 to several hours at a temperature of 400 to 600° C. in an evaporation atmosphere, whereby Se or S can also be refilled (selenization process or sulfuration process).

A manufacturing method of the compound semiconductor thin film 24 applied to the solid state image sensor for the color image pick up according to the first embodiment includes: a first step (first stage: 1a period) of holding a substrate temperature at a first temperature T1, and maintaining a composition ratio of (Cu/(In+Ga)) at zero in a state where the III-family elements are excessive; a second step (second stage: 2a period) of holding the substrate temperature at a temperature T2 higher than the first temperature T1, and shifting the composition ratio of (Cu/(In+Ga)) to 1.0 or more as a state where Cu elements are excessive: and a third step (third stage) of shifting the composition ratio of (Cu/(In +Ga)) to 1.0 or more as the state where the Cu elements are excessive to 1.0 or less as a state where the III-family elements are excessive. The third step (third stage) includes: a first period (period 3a) of holding the substrate temperature at the second temperature T2; and a second period (3b) of holding the substrate temperature at a third temperature T3 lower than the first temperature T1 from the second temperature T2, whereby the compound semiconductor thin film with the chalcopyrite structure is formed.

Moreover, the third temperature T3 is, for example, approximately 300° C. or more to approximately 400° C. or less.

Furthermore, the second temperature is, for example, approximately 550° C. or less.

Moreover, in the third step, for example, (Cu/(In+Ga)) at the ending time of the first step (period 3a) may be set, for example, in an approximate range from 0.5 to 1.3, and (Cu/(In+Ga)) at the ending time of the second step (period 3b) may be set at a value of 1.0 or less.

In the manufacturing method of the compound semiconductor thin film 24 applied to the solid state image sensor for the color image pick up according to the first embodiment, the third stage is divided into two steps. The 3a period is a high-temperature process stage with the temperature T2, and meanwhile, during the 3b period, the third stage is shifted to a low-temperature process stage with the temperature T3, and an i-type CIGS layer 242 is positively formed on the surface of the compound semiconductor thin film 24. The substrate temperature is 300° C. to 400° C., and for example, is set at approximately 300° C.

In the above description, the respective constituent elements are not evaporated simultaneously, but are evaporated separately in three stages, whereby distribution of the respective constituent elements in the film can be controlled to some extent. Beam fluxes of the In elements and the Ga elements are used for controlling the band gap of the compound semiconductor thin film 24. Meanwhile, the ratio of Cu/III family (In +Ga) can be used for controlling a concentration of Cu in the compound semiconductor thin film 24. It is relatively easy to set the ratio of Cu/III family. Moreover, it is also easy to control the film thickness. Se is always supplied by a constant amount.

It is relatively easy to set the ratio of Cu/III family (In +Ga). Accordingly, at the third stage, the ratio of Cu/III family (In +Ga) can be lowered, and the i-type CIGS layer 242 can be easily formed on the surface of the compound semiconductor thin film 24 with good controllability for the film thickness. In the i-type CIGS layer 242, a concentration of Cu that adjusts a concentration of carriers in the film is low, and the number of carriers is small, and accordingly, the i-type CIGS layer 242 functions as an i-layer.

Note that, though the description has been made above of the example of performing the low-temperature step 3b subsequently to the three-stage method; the present invention is not limited to this. For example, a method can also be adopted, in which the process is temporarily ended after the three-stage method is performed, and thereafter, the ratio of the Cu content is reduced while changing the temperature to the temperature as shown in the period 3b, and a desired CIGS surface layer is formed. Moreover, though the description has been made while taking the three-stage method as an example, the present invention is not limited to this. For example, the present invention can also be embodied, for example, by using a bilayer method. The bilayer method is a method of forming the CIGS film, for example, by the evaporation method, the sputtering method and the like by using four elements which are Cu, In, Ga and Se at the first stage, and using three elements which are In, Ga, Se excluding Cu at the subsequent second stage. After the CIGS film is formed by the bilayer method, the ratio of the Cu content is reduced while changing the temperature to the above-described temperature in the period 3b, whereby the desired CIGS surface layer can also be formed. Moreover, it is a matter of course that the present invention can be embodied by further performing such a low-temperature film formation step as mentioned above for a CIGS thin film created by using other film formation methods (a sulfuration method, a selenization/sulfuration method, a simultaneous evaporation method, an in-line simultaneous evaporation method, a high-speed solid phase selenization method, a roll-to-roll (RR) method, an ionization evaporation/RR method, a simultaneous evaporation/RR method, an electrodeposition method, a hybrid process, a hybrid sputtering/RR method, a nanoparticle printing method, a nanoparticle printing/RR method, and an FASST (registered trademark) process).

### (Multiplication Mechanism of Photoelectric Conversion Unit)

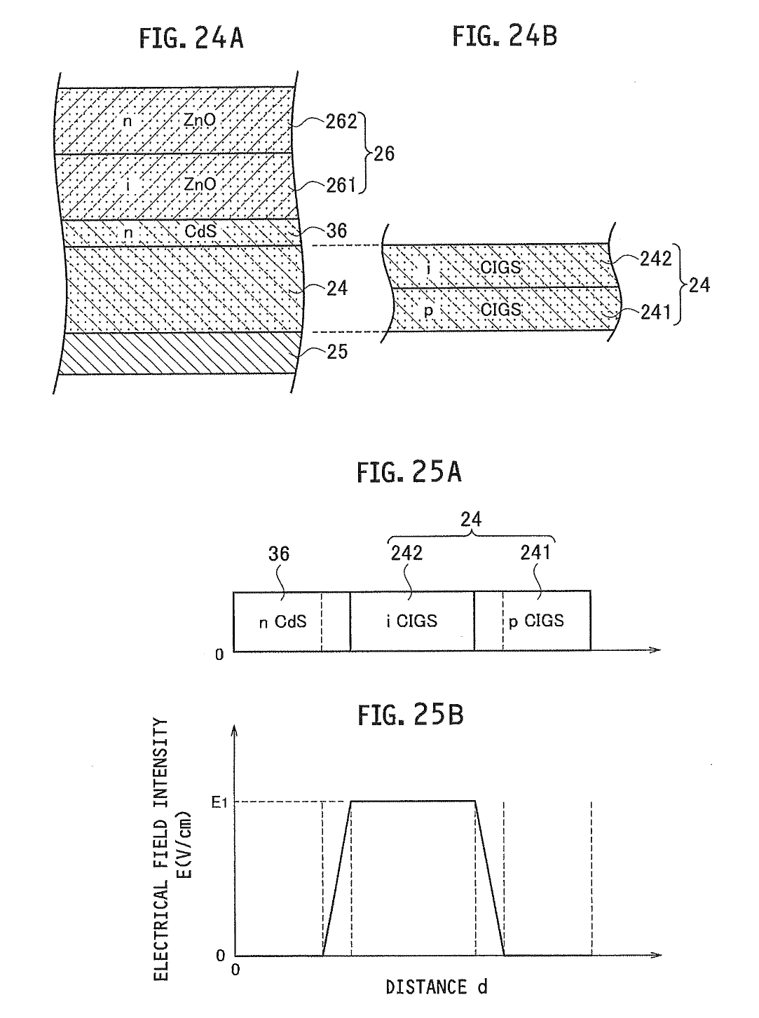

As shown in FIG. 24A, the photoelectric conversion unit 28 of the solid state image sensor for the color image pick up according to the first embodiment includes: the lower electrode layer 25; the compound semiconductor thin film 24 arranged on the lower electrode layer 25; the buffer layer 36 arranged on the compound semiconductor thin film 24; the semi-insulating layer (iZnO layer) 261 arranged on the buffer layer 36; and the upper electrode layer (nZnO layer) 262 arranged on the semi-insulating layer (iZnO layer) 261.

With this configuration, the semi-insulating layer 261 made of the non-doped ZnO layer is provided as the transparent electrode layer 26, whereby voids and holes, which occur in the underlying compound semiconductor thin film 24, can be filled with the semi-insulating layer, and a leak can be prevented. However, the configuration of the photoelectric conversion unit 28 is not limited to this, and the ZnO layer composed of the semi-insulating layer (iZnO layer) 261 and the upper electrode layer (nZnO layer) 262 can also be composed only of the upper electrode layer (nZnO layer) 262.

Moreover, the i-type CIGS layer (high-resistance layer) 24 is formed on an interface of the compound semiconductor thin film 24, which is brought into contact with the buffer layer 36. As a result, since the underlying p-type CIGS layer 241 is of the p-type, a pin junction composed of the p-type CIGS layer 241, the i-type CIGS layer 242 and the n-type buffer layer (CdS) 36 is formed as shown in FIG. 24A and FIG. 24B.

With such a structure composed of the upper electrode layer (nZnO layer) 262, the semi-insulating layer (iZnO layer) 261, the buffer layer 36, the i-type CIGS layer 242, the p-type CIGS layer 241 and the lower electrode layer 25, the leak owing to a tunnel current that occurs in the case where the conductive upper electrode layer 262 is brought into direct contact with the compound semiconductor thin film 24 can be prevented. Moreover, the semi-insulating layer 261 made of the non-doped ZnO layer is thickened, whereby a dark current can be reduced.

A thickness of the upper electrode layer 262 is, for example, approximately 200 to 300 nm, a thickness of the semi-insulating film 261 is, for example, approximately 200 nm, and as a whole, a thickness of the transparent electrode layer 26 is approximately 600 nm. A thickness of the buffer layer 36 is, for example, 100 nm. A thickness of the i-type CIGS layer 242 is, for example, approximately 200 nm to 600 nm, a thickness of the p-type CIGS layer 241 is, for example, approximately 200 nm to 600 nm, and as a whole, a thickness of the compound semiconductor thin film 24 is approximately 1.2 μm. A thickness of the lower electrode layer 25 is, for example, approximately 600 nm. The entire thickness from the lower electrode layer 25 to the transparent electrode layer 26 is, for example, approximately 1.8 μm to 3 μm.

Moreover, other electrode materials can also be applied as the transparent electrode layer 26. For example, an ITO film, a tin oxide (SnO₂) film or an indium oxide (In₂O₃) film can be used.

FIG. 25A shows a configuration view of such a compound semiconductor thin film, which forms the pin junction, in the photoelectric conversion unit 28 of the solid state image sensor for the color image pick up according to the first embodiment, and FIG. 25B shows an electrical field intensity distribution diagram corresponding to FIG. 25A.

In particular, in the case of using the Avalanche multiplication, a signal current is dramatically increased when a target voltage is increased. In such a way, the sensitivity of the sensor can be enhanced.

In the solid state image sensor for the color image pick up according to the first embodiment, in the case of using the Avalanche multiplication, a target voltage Vₜ equivalent to a reverse bias voltage for the pin junction is applied between the upper electrode layer 262 made of the n-type ZnO and the lower electrode layer 25 brought into ohmic contact with the p-type CIGS layer 241.

As shown in FIG. 25, a peak value E1 of electrical field intensity E (V/cm) is obtained on the interface of the pin junction, and accordingly, an intense electrical field is generated in the inside of the compound semiconductor thin film 24.

In the above-described structure, a value of the peak value E1 of the electrical field intensity E (V/cm) is approximately 4×10⁴ to 4×10⁵ (V/cm). The value of E1 is changed by the CIGS composition and film thickness of the compound semiconductor thin film 24. In the solid state image sensor for the color image pick up according to the first embodiment, the target voltage Vₜ just needs to be approximately 10V in order to obtain the Avalanche multiplication. Meanwhile, in the case of a usual silicon device, approximately 100V is necessary in order to obtain the Avalanche multiplication.

Moreover, in the solid state image sensor for the color image pick up according to the first embodiment, a change of a current value between the case with light irradiation and the case without the light irradiation is slight in a state where the target voltage Vₜ that is relatively low is applied thereto. Meanwhile, in a state where an Avalanche multiplication function can occur by application of a relatively high voltage, the change of the current value between the case with the light irradiation and the case without the light irradiation is extremely remarkable. A dark current in the case without the light irradiation is substantially equal between both of the states, and accordingly, an S/N ratio is also improved in the solid state image sensor for the color image pick up according to the first embodiment.

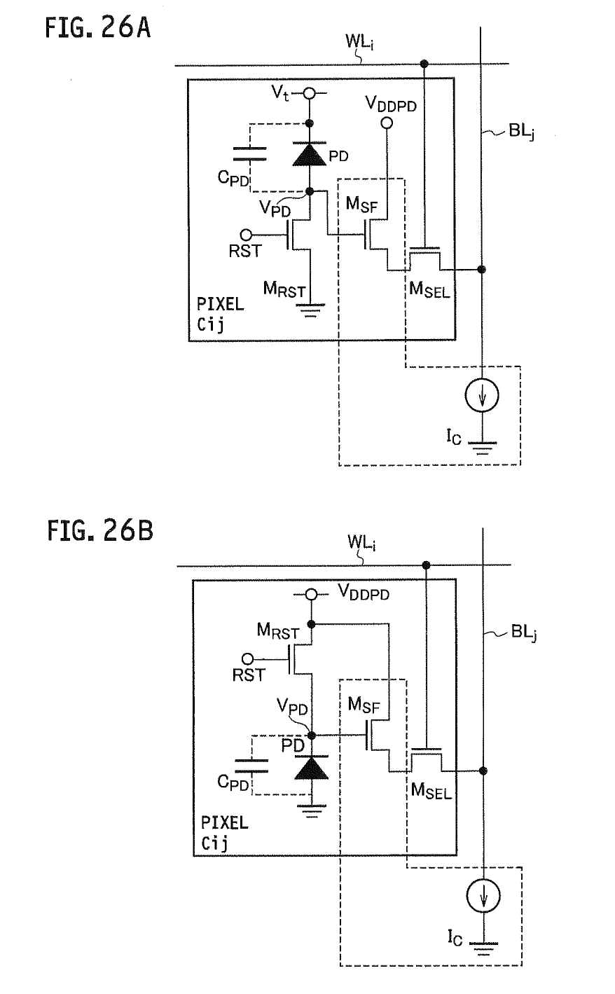

In the case of using the Avalanche multiplication, a circuit configuration of one pixel Cᵢⱼ of the solid state image sensor for the color image pick up according to the first embodiment is represented by a photodiode Pd and three MOS transistors, for example, as shown in FIG. 26A. Meanwhile, in the case of not using the Avalanche multiplication, the circuit configuration is represented as shown in FIG. 26B.

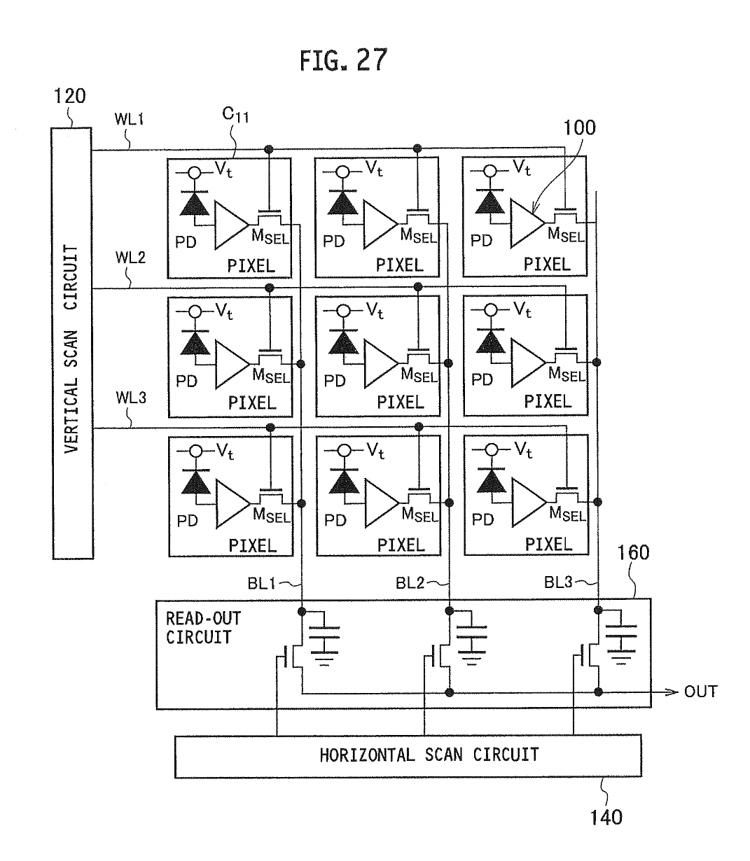

As shown in FIG. 27, the solid state image sensor for the color image pick up according to the first embodiment includes: a plurality of word lines WLᵢ (i=1 to m: m is an integer) arranged in a row direction; a plurality of bit lines BLⱼ (j=1 to n: n is an integer) arranged in a column direction; the photodiodes PD having the lower electrode layer 25, the compound semiconductor thin film 24 with the chalcopyrite structure, which is arranged on the lower electrode layer 25, and the transparent electrode layer 26 arranged on the compound semiconductor thin film 24; the visible light filters 44R, 44G and 44B arranged on the transparent electrode layer 26; the pixels Cᵢⱼ arranged on intersecting portions of the plurality of word lines WLᵢ and the plurality of bit lines BLⱼ; a vertical scan circuit 120 connected to the plurality of word lines WLᵢ; a read-out circuit 160 connected to the plurality of bit lines BLⱼ; and a horizontal scan circuit 140 connected to the read-out circuit 160. Note that, though being shown by a 3×3 matrix in the configuration example of FIG. 27, the solid state image sensor for the color image pick up according to the first embodiment is extendable to a m×n matrix. Each of the photodiodes corresponds to the photoelectric conversion unit 28 of FIG. 2.

A circuit configuration of each of the pixels shown in FIG. 27 corresponds to that of FIG. 26A. Note that the circuit configuration of FIG. 26B may also be used. Each of buffers 100 is a source follower surrounded by a broken line of FIG. 26A, and is composed of a constant current source Ic and the MOS transistor M_{SF}. Agate of the selection MOS transistor M_{SEL} is connected to the word line WL. The target voltage Vₜ (V) is applied to a cathode of the photodiode PD. A capacitor C_{PD} is a depletion layer capacitor of the photodiode PD, and is a capacitor for performing electric charge accumulation.

A drain of the MOS transistor M_{SF} for the source follower is connected to a power supply voltage V_{DDPD}. An anode of the photodiode PD is connected to the MOS transistor M_{RST} for reset, and the photodiode PD is reset to an initial state thereof at timing of a signal inputted to a reset terminal RST.

In accordance with the first embodiment, the film thickness of the compound semiconductor thin film 24 is controlled, whereby the sensitivity to the light of the near-infrared region can be allowed to be hardly given, and accordingly, infrared cut filters become unnecessary, and a solid state image sensor for the color image pick up, which has high sensitivity only to the visible region, can be provided.

In the solid state image sensor for the color image pick up according to the first embodiment, the step difference is formed in the interlayer insulating film 20, thus making it possible to control the film thickness of the compound semiconductor thin film 24 to a thickness that brings visible light sensitivity characteristics suitable for the visible light filters 44R, 44G and 44B.

At the time of obtaining a color signal, the color signal is adjusted by adjusting a white balance. However, when the absorption layer has sensitivity up to the light of the near-infrared region, such a color video signal through the absorption layer becomes unmatched with the human chromatic vision characteristics. Accordingly, accurate color reproduction characteristics cannot be obtained. Therefore, a signal processing method for obtaining the accurate color reproduction characteristics becomes necessary. However, in accordance with the solid state image sensor for the color image pick up according to the first embodiment and with the modification example thereof, the sensitivity to the near-infrared region is not given thereto, and accordingly, such signal processing becomes unnecessary.

In the solid state image sensor for the color image pick up according to the first embodiment, the film thickness of the compound semiconductor thin film 24 is controlled, whereby the configuration can be realized, in which the pixels portions having the visible light filters 44R, 44G and 44B arranged therein absorb only the visible light.

In the solid state image sensor for the color image pick up according to the first embodiment, the band gap energy Eg of the compound semiconductor thin film 24 is controlled, whereby the configuration can be realized, in which the pixels portions having the visible light filters 44R, 44G and 44B arranged therein absorb only the visible light.

In the solid state image sensor for the color image pick up according to the first embodiment, the band gap energy Eg is controlled simultaneously with the compound semiconductor thin film 24, whereby the configuration can be realized, in which the pixels portions having the visible light filters 44R, 44G and 44B arranged therein absorb only the visible light, and the pixel portions having the near-infrared filters 44I arranged therein absorb only the near-infrared light.

In accordance with the first embodiment and the modification example thereof, the solid state image sensor for the color image pick up can be provided, which does not require the infrared removal filter for the luminous efficacy correction, and matches the color reproduction characteristics thereof with the human luminous efficacy.

### Other Embodiments

The description has been made as above of the present invention by the first embodiment and the modification example thereof; however, it should not be understood that the description and the drawings, which form a part of this disclosure, limit the present invention. From this disclosure, varieties of alternative embodiments, examples and operation technologies will be obvious for those skilled in the art.

In the solid state image sensor for the color image pick up according to each of the first embodiment and the modification example thereof, for the photoelectric conversion unit, Cu(In_{X}, Ga_{1-X})Se₂ (0≦X≦1) is used as the compound semiconductor thin film having the chalcopyrite structure; however, the present invention is not limited to this.

As the CIGS thin film applied to the compound semiconductor thin film, one having a composition of Cu(In_{X}, Ga_{1-X})(Se_{Y}, S_{1-Y}) (0≦X≦1, 0≦Y≦1)) is also known, and the CIGS thin film having such a configuration is also usable.

Besides these, as the compound semiconductor thin film with the chalcopyrite structure, other compound semiconductor thin films are also applicable, such as CuAlS₂, CuAlSe₂, CuAlTe₂, CuGaS₂, CuGaSe₂, CuGaTe₂, CuInS₂, CuInSe₂, CuInTe₂, AgAlS₂, AlAlSe₂, AgAlTe₂, AgGaS₂, AgGaSe₂, AgGaTe₂, AgInS₂, AgInSe₂, and AgInTe₂.

Moreover, as the embodiment, the description has been made above of the configuration including the buffer layer; however, the present invention is not limited to this. A configuration may also be adopted, in which the transparent electrode layer 26 is provided on the compound semiconductor thin film (CIGS) layer without the buffer layer.

Furthermore, in the solid state image sensor for the color image pick up according to the first embodiment, the description has been mainly made of the configuration in which the anode of each of the photodiodes composed of the compound semiconductor thin film 24 is connected to the gate electrode of the MOS transistor of the circuit section, that is, an example where an amplification function is provided in a unit of the pixel; however, the configuration of the circuit section 30 is not limited to such a configuration, and there may also be adopted a configuration in which the anode of the photodiode is connected to the source or drain electrode of the MOS transistor of the circuit section, that is, an example where the amplification function is not provided in a unit of the pixel.

Moreover, in the solid state image sensor for the color image pick up according to the first embodiment, the description has been mainly made of the example where the Avalanche multiplication function is provided in the photodiode composed of the compound semiconductor thin film 24; however, the configuration of the photoelectric conversion unit 28 is not limited to the case where the Avalanche multiplication function is provided. A photodiode of the compound semiconductor thin film 24, which does not have the Avalanche multiplication function, may also be used.

As described above, it is a matter of course that the present invention incorporates the variety of embodiments and the like, which are not described herein. Hence, the technical scope of the present invention should be determined only by the invention specifying items according to the scope of claims reasonable from the above description.

### INDUSTRIAL APPLICABILITY

The solid state image sensor for the color image pick up according to the present invention is applicable to a color image sensor for the visible light, a color image sensor for a security camera (camera that senses the visible light in the daytime, and senses the near-infrared light at night), a personal identification camera (camera for identifying a person by the near-infrared light that is not affected by external light), or an on-board camera (camera mounted on a vehicle in order to assist a visual sense at night, to ensure a remote viewing field, and so on), and the like.

1. A solid state image sensor for color image pick up, comprising:
a circuit section formed on a substrate;
a lower electrode layer arranged on the circuit section;
a compound semiconductor thin film with a chalcopyrite structure, the compound semiconductor thin film being arranged on the lower electrode layer;
a transparent electrode layer arranged on the compound semiconductor thin film; and
a filter arranged on the transparent electrode layer,
wherein the lower electrode layer, the compound semiconductor thin film and the transparent electrode layer are sequentially stacked on the circuit section, and in addition, thin a film thickness of the compound semiconductor thin film below the filter, and absorb only visible light.

2. The solid state image sensor according to claim 1, further comprising:
an infrared filter arranged on the transparent electrode layer,
wherein the film thickness of the compound semiconductor thin film below the filter is thinned more than a film thickness of the compound semiconductor thin film below the infrared filter, and the compound semiconductor thin film below the infrared filter absorbs only infrared light.

3. The solid state image sensor according to claim 1, wherein near-infrared light is adapted not to be absorbed by controlling band gap energy of the compound semiconductor thin film.

4. The solid state image sensor according to claim 3, wherein the band gap energy of the compound semiconductor thin film is increased by increasing a Ga content of the compound semiconductor thin film.

5. The solid state image sensor according to claim 3, wherein the band gap energy of the compound semiconductor thin film is increased by reducing a Cu content of the compound semiconductor thin film.

6. The solid state image sensor according to claim 3, wherein the band gap energy of the compound semiconductor thin film is increased by reducing an In content of the compound semiconductor thin film.

7. The solid state image sensor according to claim 1, wherein the circuit section includes a transistor in which the lower electrode layer is connected to a gate.

8. The solid state image sensor according to claim 1, wherein the circuit section includes a transistor in which the lower electrode layer is connected to either one of a source and a drain.

9. The solid state image sensor according to claim 1, wherein the compound semiconductor thin film with the chalcopyrite structure is formed of Cu(In_{X}, Ga_{1-X})Se₂ (0≦X≦1).

10. The solid state image sensor according to claim 1, wherein the transparent electrode layer includes a non-doped ZnO film provided on the compound semiconductor thin film, and an n-type ZnO film provided on the non-doped ZnO film.

11. The solid state image sensor according to claim 1, wherein the compound semiconductor thin film includes a high-resistance layer on a surface thereof.

12. The solid state image sensor according to claim 4, wherein the Ga content is 0.4 to 1.0.

13. The solid state image sensor according to claim 5, wherein the Cu content is 0.5 to 1.0.

14. A solid state image sensor for color image pick up, comprising:
a circuit section formed on a substrate;
a plurality of word lines WLᵢ (i=1 to m: m is an integer) arranged in a row direction;
a plurality of bit lines BLⱼ (j=1 to n: n is an integer) arranged in a column direction;
photodiodes including a lower electrode layer, a compound semiconductor thin film with a chalcopyrite structure, the compound semiconductor thin film being arranged on the lower electrode layer, and a transparent electrode layer arranged on the compound semiconductor thin film;
filters arranged on the transparent electrode layer; and
pixels arranged on intersecting portions of the plurality of word lines WLᵢ and the plurality of bit lines BLⱼ,
wherein the lower electrode layer, the compound semiconductor thin film and the transparent electrode layer are sequentially stacked on the circuit section, and in addition, thin a film thickness of the compound semiconductor thin film below the filter, and absorb only visible light.

15. The solid state image sensor according to claim 14, further comprising:
an infrared filter arranged on the transparent electrode layer,
wherein the film thickness of the compound semiconductor thin film below the filter is thinned more than a film thickness of the compound semiconductor thin film below the infrared filter, and the compound semiconductor thin film below the infrared filter absorbs only infrared light.

16. The solid state image sensor according to claim 14, wherein near-infrared light is adapted not to be absorbed by controlling band gap energy of the compound semiconductor thin film.

17. The solid state image sensor according to claim 16, wherein the band gap energy of the compound semiconductor thin film is increased by increasing a Ga content of the compound semiconductor thin film.

18. The solid state image sensor according to claim 16, wherein the band gap energy of the compound semiconductor thin film is increased by reducing a Cu content of the compound semiconductor thin film.

19. The solid state image sensor according to claim 14, further comprising:
a vertical scan circuit connected to the plurality of word lines WLᵢ;
a read-out circuit connected to the plurality of bit lines BLⱼ; and
horizontal scan circuit connected to the read-out circuit.

20. The solid state image sensor according to claim 14, wherein the pixels includes transistors for selection, in which gates are connected to the word lines WLᵢ (i=1 to m: m is an integer), and drains are connected to the bit lines BLⱼ (j=1 to n: n is an integer).
